(19) United States
(12) Patent Application Publication
(10) Pub. No.: US 2024/0023300 A1
(43) Pub. Date: Jan. 18, 2024

(54) EMF PROTECTIVE DEVICE

(71) Applicant: Matthew Riley, Swarthmore, PA (US)

(72) Inventor: Matthew Riley, Swarthmore, PA (US)

(21) Appl. No.: 18/298,519

(22) Filed: Apr. 11, 2023

Related U.S. Application Data
(60) Provisional application No. 63/388,294, filed on Jul. 12, 2022.

(51) Int. Cl. H05K 9/00; A45C 11/00

(52) U.S. Cl. CPC H05K 9/0043; A45C 11/00; H05K 9/009; H05K 9/006

(57) ABSTRACT

A retaining device for an EMF-generating device includes a first surface or opening which is transparent to the EMF of the EMF-generating device, and a second surface which is at least partially opaque to the EMF generated by the EMF-generating device. The device can be installed such that the second surface is oriented towards an individual or pet while the first surface faces away.

### CROSS REFERENCE TO RELATED APPLICATION

This application claims the benefit of U.S. Provisional Patent Application 63/388,294, filed Jul. 12, 2022, which is incorporated herein by reference.

### BACKGROUND OF THE INVENTION

### 1. Field of the Invention

The present invention relates to devices for protection against electromagnetic radiation.

### 2. Background of the Invention

Tracking devices for monitoring the location of objects are known. Typically, such tracking devices emit electromagnetic radiation which can be remotely monitored to locate the tracking device. One popular type of tracking device employs the Global Positioning System. Tracking devices are popularly employed to try to locate objects, including vehicles such as stolen automobiles and motorcycles, keys that have been misplaced, and other assets. Tracking devices also find use to keep track of individuals, such as small children, individuals with special needs, and the elderly, as well as pets including dogs and cats.

Tracking devices can employ GPS to identify the location of the tracked object or person, and wireless cellular technology to report the location. Some devices report to a central facility which then provides a report to a party interested in the location of the device. Frequently, a subscription service is required.

As EMF, GPS, CPS, 4G, 5G, Bluetooth, and Wi-Fi tracking devices enter the marketplace, consumers may simply assume that they can safely track children, pets, mentally or emotionally disabled loved ones, or those debilitated by Alzheimer's, dementia or other memory or cognitive functioning diseases. They understand, perhaps incorrectly, that such tracking devices are safe to use. However, this may be incorrect.

Tracking devices typically emit some type of EMF radiation. Manufacturers of tracking devices have often provided a warning advising against the placement of trackers on children and pets, out of concern that the radiation frequency emitted could be hazardous to their health. Some studies have suggested that prolonged exposure to EMF radiation is associated with headaches, anxiety, depression, nausea, fatigue, and even cancer.

Nevertheless, these concerns have not deterred some parents and caretakers from purchasing tracking products presently available on the market, as well as children's bracelets, keychains, and lanyards, and pet collars specifically designed for the purpose of housing these tracking devices.

More recently, tracking devices based on Bluetooth technology have become available. These rely on transmitting a Bluetooth signal, which, having a relatively short range, must be received by a Bluetooth-enabled receiving device that is relatively nearby, and which is configured to receive the signal received from the tracking device. For example, an Android cell phone provided with a suitable app can receive the tracking device's location signal (such as an Android compatible tracking device such as those marketed by Tile, Inc.) and forward it to another cell phone, such as the cell phone of the tracking device's owner. Until recently, this method suffered from a paucity of suitably enabled receiving devices. However, within the last year, Apple has introduced its own miniaturized tracking device, the AirTag, which relies on a huge pre-existing network of Apple devices to sense the location of the tracking device, without the need for the installation of a special app on an Apple phone. Apple's more recent phones have been equipped with ultra-wide bank (“UWB”) technology, enabling more precise location of AirTags.

Tracking devices have proven very useful for locating lost objects and pets. However, some questions have been raised concerning the safety of using tracking devices on individuals, and in particular, children. Tracking devices such as the AirTag emit a Bluetooth signal. Perhaps out of apprehension of liability for personal injury associated with exposure to AirTag's EMF radiation, Apple advises against the use of AirTags to help locate persons or pets.

For a parent, the obligation of care extends especially to the physical location of small children, who must be protected against dangers they are not yet aware of. Thus, depending on the situation, using a Bluetooth device to track a small child has great appeal. Use by a prudent parent would be determined by balancing this appeal against the possibility of future harm by virtue of the additional exposure to EMF radiation from the tracking device. However, this latter quantity likely cannot be reliably estimated. The present invention suggests a solution to the problem posed by this choice.

Currently, various pouches, bags, pockets, cages, and the like are available formed from EMF reducing fabrics. These devices are designed to provide a complete enclosure or “Faraday cage” to limit the transmission of EMF radiation to or from objects such as cell phones placed within the device to avoid tracking or intrusion.

### SUMMARY OF THE INVENTION

The present invention provides a retaining device for an EMF-generating device. The retaining device includes a first surface or opening which is transparent to the EMF of the EMF-generating device, and a second surface which is at least partially opaque to the EMF generated by the EMF-generating device. The retaining device is preferably adapted to be installed such that the second surface is oriented towards the individual or pet, such that the first surface faces outward away from the individual or pet. In one aspect of the present invention, the EMF-generating device is a Bluetooth tracking device. Preferably, the retaining device takes the form of a pouch for receiving the tracking device. The pouch is preferably formed from a generally flexible material(s), preferably a textile fabric or mesh. Preferably, the back side of the pouch is formed from or includes an EMF blocking material, which is preferably formed into protective fabrics, screens, or inks. In one embodiment, the EMF blocking material includes highly conductive metals. In one embodiment, the front side of the pouch is preferably formed from a cotton fabric. Preferably, the pouch is formed by sewing or otherwise adhering together the front and back of the pouch along their edges. In another aspect of the present invention, the geometry of the retaining device can be adapted to the geometry of the tracking device. In one embodiment of the present invention, the geometry of the retaining device is adapted to that of a disk-shaped tracking device.

### BRIEF DESCRIPTION OF THE DRAWINGS

FIG. 1 is a front elevational view of an EMF protective device according to the present invention formed from two overlapping rectangular strips 1 of elastic material adhered to one another by stitching 2.

FIG. 2 is a side elevational view of the EMF protective device of FIG. 1 showing an exterior strip of elastic material 1 adhered by stitching 2 to a strip of EMF blocking or reducing material 3. An entry point 4 is provided for placing an EMF emitting device within the protective device.

FIG. 3 is a rear elevational view of the EMF protective device of FIG. 1.

FIG. 4 is an exploded front elevational view of the EMF protective device of FIG. 1.

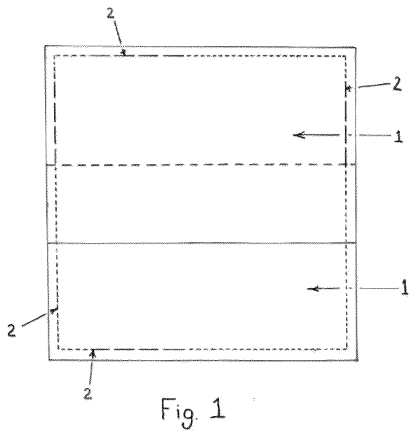

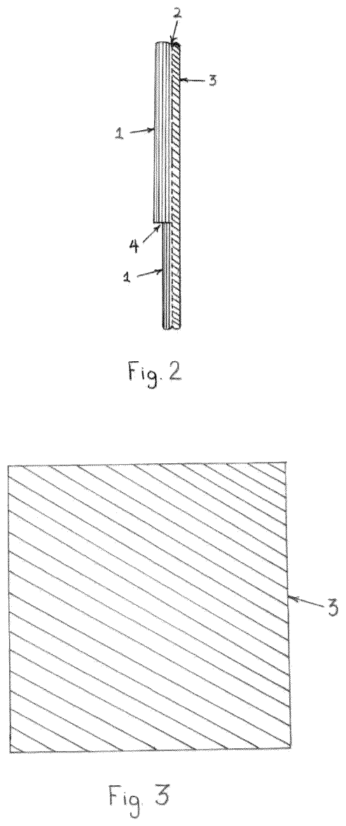

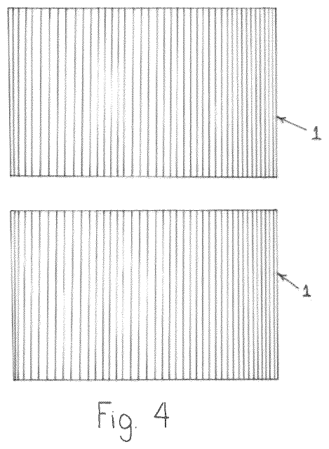

### DETAILED DESCRIPTION OF THE INVENTION

This invention provides a retaining device for an EMF-generating device, and in particular, for an EMF-generating tracking device, such as a Bluetooth tracking device, a tracking device operating on more than a single network, such as the Apple AirTag, or a GPS tracking device. The retaining device includes a first surface or opening which is transparent to the EMF generated by the tracking device, and a second surface which is at least partially opaque to EMF generated by the tracking device. The retaining device is adapted to be installed such that the second surface is oriented towards the individual or pet, such that the first surface faces outward away from the individual or pet. The present invention thus provides directional EMF blocking against the skin side of the wearer, while still allowing the tracking device to communicate with various networks by not fully enclosing the tracker, thereby creating a “Faraday cage” where the enclosed electromagnetic field would render the tracker useless.

In one aspect, the retaining device takes the form of a pouch for receiving the tracking device. Preferably, the geometry of the retaining device is adapted to the geometry of the tracking device. For example, when a disk-shaped AirTag tracking device is used, the retaining device can take the form of a pouch formed from generally flexible material(s), such as a textile fabric or mesh. Preferably, the back side of the pouch is formed from or includes an EMF blocking material. By “EMF blocking material” is meant a material that reflects or absorbs a substantial portion of incident radio frequency wave energy, preferably at least 90 percent of energy of incident RF radiation, and more preferably, at least 99 percent. Examples of EMF blocking material include highly conductive metals such as silver and copper, which may be formed into protective fabrics, screens, or inks, such as a copper wire mesh, while the front side of the pouch is formed from, for example, a cotton fabric. The pouch is formed by sewing or otherwise adhering together the front and back of the pouch along their edges.

The pouch can be rectangular, have a downwardly arced bottom, etc. The pouch can be sewn or otherwise adhered to, for example, a child's clothing or possessions (e.g., favorite toy or blanket). For example, since clothing frequently includes a sewn-in label positioned on the inside of the back portion of the clothing, the pouch can be attached there (e.g., rear of waistband for underwear or pants) or preferably, on the outside of a garment facing that label.

In one presently preferred embodiment of the invention, the invention provides a small pouch for receiving a Bluetooth tracking device. In this embodiment, the back facing panel, or skin side panel, is formed from an EMF reducing fabric (“Faraday fabric”), while the front panel is constructed from an elastic fabric material. The pouch is then stitched or ironed onto children's underwear, onesies, dog collars, or the favorite article of clothing of an elderly person with dementia, etc.

Thus, in this embodiment, the present invention provides a comfortable, covert “pocket,” that will not lose the tracking device, and which will protect the wearer of the clothing article containing the pocket housing the tracking device. The present invention thus provides peace of mind to parents taking their children to an amusement park, or who would like to confirm the story of a babysitter, or who simply would like to stay informed of their child's location.

Preferably, the materials used to construct the product, the means of fabrication, the size and the location of attachment are selected to minimize awareness of the tracking device by the person or animal wearing the device. Frequently, a bracelet, keychain or lanyard worn by a child will be taken off by the child impulsively and with impunity. Securing the device to a child's underwear, which are often the last articles of clothing to be removed, enhances the reliability of the tracker.

In a presently preferred embodiment, the invention provides a pocket or pouch that is formed from three strips of fabric. The rear panel (skin side panel) is made of Faraday fabric. Two front overlapping panels are provided to a tracking device. These panels are made of an elastic material fabric which is both comfortable to the wearer and secure enough to house the device without risk of loss. The pouch is sewed or adhered onto children's underwear, dog collars, onesies, or any other article of clothing for a person or pet that wishes to be tracked comfortably, safely, and covertly, if necessary (in the case of small children).

Various modifications can be made in the details of the various embodiments of the apparatus of the present invention, all within the scope and spirit of the invention as defined by the appended claims.

1. A retaining device for an EMF-generating device, the retaining device including a first surface or opening which is transparent to the EMF of the EMF-generating device, and
a second surface which is at least partially opaque to the EMF generated by the EMF-generating device;
the retaining device being adapted to be installed such that the second surface is oriented towards the individual or pet, such that the first surface faces outward away from the individual or pet.

2. A retaining device according to claim 1, wherein the EMF-generating device is a Bluetooth tracking device.

3. A retaining device according to claim 1, wherein the retaining device takes the form of a pouch for receiving the tracking device.

4. A retaining device according to claim 1, wherein the geometry of the retaining device is adapted to the geometry of the tracking device.

5. A retaining device according to claim 4, wherein the geometry of the retaining device is adapted to that of a disk-shaped tracking device.

6. A retaining device according to claim 3, wherein the pouch is formed from generally flexible material(s).

7. A retaining device according to claim 3, wherein the pouch is a textile fabric or mesh.

8. A retaining device according to claim 3, wherein the back side of the pouch is formed from or includes an EMF blocking material

9. A retaining device according to claim 8, wherein the EMF blocking material includes highly conductive metals.

10. A retaining device according to claim 3, wherein the EMF blocking material is formed into protective fabrics, screens, or inks.

11. A retaining device according to claim 3, wherein the front side of the pouch is formed from a cotton fabric.

12. A retaining device according to claim 3, wherein the pouch is formed by sewing or otherwise adhering together the front and back of the pouch along their edges.
